(19) United States
(12) Patent Application Publication
(10) Pub. No.: US 2016/0116211 A1
(43) Pub. Date: Apr. 28, 2016

(54) OPERATING METHOD AND DEVICE FOR IRRADIATING A SUBSTRATE

(71) Applicant: HERAEUS NOBLELIGHT GMBH, Hanau (DE)

(72) Inventors: Jürgen WEBER, Kleinostheim (DE); Sven LINOW, Darmstadt (DE); Oliver WEISS, Heusenstamm (DE)

(21) Appl. No.: 14/896,163

(22) PCT Filed: May 26, 2014
(86) PCT No.: PCT/EP2014/060832

§ 371 Date: Dec. 4, 2015

(30) Foreign Application Priority Data
Jun. 7, 2013 (DE) 10 2013 105 959.7

(51) Int. Cl. F26B 3/30; H01L 21/67

(52) U.S. Cl. CPC F26B 3/30; H01L 21/67115

(57) ABSTRACT

A method is provided for operating a device for modifying a substrate with an irradiating unit in which multiple cylindrical infrared emitters having longitudinal axes arranged parallel to one another are grouped together. The method includes the steps (a) specifying a total radiation output power as a function of the substrate modification to be achieved, (b) operating each infrared emitter at a desired operating output power, (c) specifying a desired radiation spectrum as a function of the substrate modification to be achieved, and (d) selecting the desired operating output power of each infrared emitter individually so that, when the output powers are added together, the desired radiation spectrum and the total radiation output power are obtained, (e) with the proviso that the infrared emitters are of an identical construction and that the total radiation output power deviates by a maximum of 15% from a specified desired value.

### CROSS-REFERENCE TO RELATED APPLICATIONS

This application is a Section 371 of International Application No. PCT/EP2014/060832, filed May 26, 2014, which was published in the German language on Dec. 11, 2014, under International Publication No. WO 2014/195172 A1 and the disclosure of which is incorporated herein by reference.

### BACKGROUND OF THE INVENTION

The present invention relates to a method for operating a device for modifying a substrate by irradiation with infrared radiation, comprising an irradiating unit in which multiple cylindrical infrared emitters having longitudinal axes arranged parallel to one another are grouped together, comprising the method steps:
(a) specifying a total radiation output power as a function of the substrate modification to be achieved, and
(b) operating each infrared emitter with a desired operating output power.

Furthermore, the present invention relates to a device for modifying a substrate by irradiation with infrared radiation with an irradiating unit in which multiple cylindrical infrared emitters having longitudinal axes arranged parallel to one another are grouped together.

Devices for modifying a substrate in the sense of the invention are infrared heating devices; they are used, for example, for drying and curing of coatings, adhesives, or paints.

Known devices have a processing chamber for holding the substrate as well as several infrared emitters for irradiating the substrate. The infrared emitters comprise an illuminating tube made of quartz glass closed on both ends, in which there is a heating element, for example in the form of a carbon band or a tungsten wire. The illuminating tube of the infrared emitter is filled with an inert gas.

Such an irradiating device is known, for example, from German published patent application DE 100 51 125 A1, which discloses a quick heating system for semiconductor wafers. The irradiating device has a rotatably supported holder for a substrate and multiple infrared emitters having a linear, cylindrical, elongated emitter tube in which there is a glow wire made of tungsten. In addition, a control unit for the individual electrical driving of the infrared emitters is provided, which can be used to set the irradiating output power of the infrared emitters.

The adjustability of the irradiation output power allows the irradiation process to be optimized. In principle, this allows a faster irradiation process when the irradiation output power of the infrared emitters is selected as high as possible, so that there is a high energy transfer into the substrate. However, the maximum usable irradiation output power that can be used in an irradiation process depends on the substrate to be irradiated. Often the substrate is sensitive to temperature, so that a too high irradiation output power causes overheating and thus damage to the substrate. In addition, the irradiation spectrum of the infrared emitters also influences the irradiation process. Thermally sensitive substrates often have an absorption spectrum that is strongly dependent on wavelength, so that for efficient irradiation of the substrate, radiation having a high percentage of radiation in certain wavelength ranges is necessary. Here, the spectrum emitted by the infrared emitters sometimes determines whether an irradiation process can be performed at all.

Therefore, to be able to use an irradiating device for irradiating different substrates, it is necessary to be able to generate different emission spectra. Here, typically the irradiating device must be retrofitted with different infrared emitters. This, however, requires a cost-intensive provision of multiple infrared emitters having different emission spectra or, alternatively, a certain amount of retrofitting time for installing different infrared emitters, wherein the productivity can be negatively affected by changes being necessary for irradiating a different substrate.

One special field of use for irradiating devices according to the invention is the drying and sintering of inks that contain metal, like those used in the production of printed electronics, for example electronic switch elements, RFIDs, organic photovoltaics, OLEDs, or printed batteries. In the production of printed electronics, in a first processing step, the metal-containing inks are first deposited as a thin layer by a printing method onto a suitable substrate, for example onto a plastic film, paper, or glass. The thickness of the ink layer is usually between 0.3 μm and 3.0 μm. For depositing the ink layer, a number of different printing methods can be used. Often screen printing, the roll-to-roll method, or ink-jet printing are used.

Inks that are used for the production of printed electronics contain a high percentage of small metal particles, whose particle size is frequently in the nanometer range. The metal particles are dispersed in an aqueous or organic dispersant. In addition, the inks can contain organic additives, for example for better particle cross-linking, solubility, wettability, or for preventing agglomeration, or instead aqueous additives for better processability of the inks. To obtain an electrically conductive and durable coating of the substrate, it is necessary to dry and sinter the ink coating with the irradiating device in a second processing step.

Such an irradiating device for the production of printed electronics is known, for example, from U.S. Patent Application Publication 2010/0003021 A1. This unit has a radiation source that is suitable for the emission of radiation having wavelengths in the visible, infrared, and/or UV range. In addition, the unit comprises a control unit for controlling the irradiation as a function of optical properties of the hardening coating. The control unit optically detects the degree of hardening of the coating and regulates the total irradiation output power emitted by the radiation sources as a function of this detected quantity.

For this unit, retrofitting of the infrared emitters is also regularly required if the unit is to be used for the irradiation of different substrates.

### BRIEF SUMMARY OF THE INVENTION

The invention is therefore based on the object of providing an efficient operating method that makes a simple and fast retrofitting of the unit for a new operating mode and simultaneously a simple and economical operation of the unit possible.

The invention is also based on the object of providing a unit that can be retrofitted simply and quickly for a new operating mode and can be operated simply and economically.

With respect to the operating method, this object is achieved according to the invention starting with an operating method for a device for modifying a substrate of the type mentioned above, such that
(c) a desired radiation spectrum is specified as a function of the substrate modification to be achieved, and
(d) the desired operating output power of each infrared emitter is selected individually such that when the output powers are added together, the desired radiation spectrum and the total radiation output power are obtained,
(e) with the proviso that the infrared emitters are of an identical construction and the total radiation output power deviates by a maximum of 15% from a specified desired value.

Devices used for modifying a substrate have an irradiating unit that irradiates the substrate with infrared radiation. In these devices the irradiating unit and the substrate usually can be moved relative to each other. The radiation emitted by the irradiating unit is characterized on the one hand by its irradiation output power and on the other hand by its radiation spectrum.

The total irradiation output power influences the heating of the substrate during the irradiation; it determines the maximum temperature of the substrate during the irradiation. In principle, a too high total irradiation output power can be associated with damage to the substrate.

In contrast, the irradiation spectrum influences the effectiveness of the irradiation process. Often, for an effective irradiation process, radiation having a high radiation percentage in a specified wavelength range is required. In particular, for thermally sensitive substrates, which have a strongly wavelength-dependent absorption spectrum or are composed of multiple components having different spectral properties, the emission spectrum can influence the efficiency of the irradiation method; the emission spectrum achieved sometimes determines whether an irradiation method can be performed at all.

Therefore, for many irradiation processes it is desirable to be able to set both the total irradiation output power and also the radiation spectrum.

In a unit for irradiating a substrate, to be able to set both the total irradiation output power and also the radiation spectrum emitted by the infrared emitters, according to the invention, initially multiple infrared emitters are provided each of which can be operated at an individually set desired operating output power.

Infrared emitters are thermal emitters whose emission spectrum depends essentially on the temperature of their heating element. For these emitters, the emission spectrum has a maximum energy density at a certain wavelength; the associated wavelength is designated the main emission line.

The position of the main emission line is defined by the temperature of the infrared emitter. The wavelength of the main emission line becomes larger the colder the infrared emitter becomes. Therefore, by the suitable selection of the temperature of the infrared emitter, the main emission line can be adjusted. When the temperature is changed, the wavelength distribution is changed at the same time, that is, the entire spectrum. The wavelength distribution of a spectrum emitted by an infrared emitter can be described approximately by Planck's radiation law. According to this law, the spectral emission output power of a material can be described by the following formula:

$$E ( λ , T ) = \frac{{c}_{1}}{{λ}^{5}} \frac{ɛ ( λ , T )}{{e}^{( {c}_{2} / λ T )} - 1}$$

where E (λ, T) is the spectral emission output power, c₁, c₂ are constants, λ is the wavelength, T is the temperature, and ε (λ, T) is the spectral emissivity of the surface.

This type of adjustment of the radiation spectrum is basically known for UV emitters. Thus, from German published patent application DE 101 45 648 A1 a UV irradiating device is known whose radiation spectrum can be set on one hand by multiple radiation sources having different emission spectra and on the other hand by adjusting the operating output power of the UV emitters. However, by changing the supply of output power in UV emitters, essentially only the total supplied energy quantity can be increased or reduced. In contrast, the distribution of energy relative to wavelength changes only slightly. Therefore, for such irradiating devices, the provision of different radiation sources is important.

When operating at reduced operating output power, UV emitters do indeed exhibit a lower emitter temperature. But the adjustment of the spectrum here involves the fact that the temperature changes due to the gas composition changing in the discharge chamber of the UV emitter, for example, that the metallic additives of the filler gas condense in the discharge chamber; therefore, this solution cannot be transferred to infrared emitters without additional means.

Indeed, for infrared emitters the illuminating tube is also frequently filled with an inert gas, so that a high temperature of the heating element and thus a high output power of the infrared emitters can be possible. However, the inert gas does not appreciably contribute to emissions in the infrared spectral range and a change of the gas composition when the infrared emitters are cooled is not observed.

Each infrared emitter arranged in the irradiating unit has an individual emission spectrum and an individual irradiation output power. With respect to the overall irradiating unit, the individual radiation spectra of the infrared emitters overlap and form a mixed spectrum. The total irradiation output power is the integral irradiation output power in watts with respect to the emission surface area of the emitter arrangement. Because the total irradiation output power of the irradiating unit is given from the sum of the individual irradiation output powers, by varying the number of emitters, the total irradiation output power can be changed. Here, the infrared emitters can be operated both with the same operating output powers or with different operating output powers, so that the substrate is irradiated conditionally by the overlap of the spectra with a mixed spectrum that corresponds to the specified radiation spectrum.

Because multiple infrared lamps according to the invention are provided, individual infrared emitters can be switched off or on, in order to maintain the desired radiation spectrum and simultaneously the specified total irradiation output power. In particular, the infrared emitters can be operated with a lower operating output power (dimmed operation). The infrared emitters can be controlled individually and are each operated at their individual operating output power.

According to the invention, the desired operating output power of each infrared emitter is to be selected individually so that, when the output powers are added together, the desired radiation spectrum and the total irradiation output power are produced, under the provision that the infrared emitters are of an identical construction and the total radiation output power deviates by a maximum of 15% from a specified desired value. The desired value of the total irradiation output power and the maximum permissible deviation from this desired value are selected so that damage to the substrate is prevented. The total irradiation output power also has influence on the duration and speed of the irradiation process. For a deviation of the total irradiation intensity of at most 15% from the specified desired value, the speed of the irradiation process is subjected to only insignificant adverse effects.

In addition, a unit having multiple structurally identical infrared emitters is easy to produce; it enables a simple control of the operating output power of each infrared emitter, because only one infrared emitter type has to be taken into account. Because different infrared emitters do not have to be kept in stock, investment and operating costs are kept low.

Preferably, a control unit is provided that determines the operating output power of each individual infrared emitter with the specification of the radiation spectrum to be set and a specified desired value of the total irradiation intensity to be set.

In one preferred embodiment of the operating method according to the invention, it is provided that the infrared emitters have a nominal output power and that each desired operating output power is either 0% of the nominal output power or is in the range from 15% up to and including 100% of the nominal output power.

The nominal output power of the infrared emitters is the maximum output power at which it can be continuously operated for proper operation without significantly adversely affecting the service life. The operating output power at which each infrared emitter is actually operated can be expressed as a percentage of the nominal output power.

A dimmed operation of the infrared emitter can negatively affect the efficiency of the infrared emitter. To guarantee efficient operation of the unit it has proven effective when the infrared emitters are operated either at an operating output power that is in the range from 15% up to and including 100% of the nominal output power or are switched off, that is, are operated at 0% of the nominal output power.

An especially efficient operation of the unit is guaranteed if each desired operating output power is either 0% of the nominal output power or in the range from 50% up to and including 100% of the nominal output power.

In another preferred embodiment of the operating method according to the invention, it is provided that each infrared emitter emits radiation having a percentage of IR-A radiation of at least 25% and IR-B radiation of at least 25% with respect to the total radiation output power of each infrared emitter.

IR-A radiation has wavelengths in the range from 0.78 μm to 1.4 μm; the wavelengths of IR-B radiation are in the range from 1.4 μm to 3.0 μm and those of IR-C radiation in the range from 3 μm to 1000 μm. Infrared radiation in the IR-A range has a higher radiation energy compared to IR-B radiation. In principle, the following applies: the greater the radiation energy, the shorter the irradiation process can be selected. The IR-A radiation percentage therefore contributes to an efficient operating method. IR-B radiation is absorbed well by many substrates. Good irradiation results are therefore achieved when the infrared emitters emit radiation having a radiation percentage of IR-A radiation of at least 25% and a radiation percentage of IR-B radiation of at least 25%.

It has proven effective when the desired operating output power of the infrared emitters is determined by a control unit.

Because the control unit determines the desired value of the operating output power, this value can be easily adapted to different operating conditions. The desired value of the operating output power is provided directly for a corresponding control of the operating output power.

In one preferred modification of the operating method according to the invention, it is provided that the unit comprises non-illuminated infrared emitters and illuminated infrared emitters, wherein adjacent illuminated infrared emitters have an illumination spacing relative to each other, wherein the variance of the average value of the illumination spacings of the unit assume a minimum.

In one unit having multiple infrared emitters, for setting the total irradiation intensity and the radiation spectrum, not all of the infrared emitters have to be illuminated. The illuminated infrared emitters here irradiate an irradiation pattern onto the surface of the substrate. Adjacent illuminated infrared emitters are indirectly adjacent to one another or are separated from each other by one or more non-illuminated infrared emitters. The illumination spacing is the shortest distance of the emitter tubes of adjacent infrared emitters. To enable the most uniform irradiation of the irradiation field possible, the illuminated infrared emitters are arranged in the unit such that the average value of the illumination spacings has lowest possible spread.

It has proven favorable when the control unit has a memory element that stores the characteristic curves of the infrared emitters, and when at least one of the characteristic curves is included in the determination of the desired values of the operating output power of each infrared emitter.

The memory element is preferably an electronic memory element, for example, an EEPROM or flash memory. The memory element stores the characteristic curves of the infrared emitters that are characteristic for each infrared emitter. In this sense, characteristic curves are, for example, current-voltage curves, radiation output power-temperature curves, emission spectra, absorption curves, reflection curves. From the characteristic curves, the control unit determines the individual operating output powers of each infrared emitter and from this the total irradiation output power to be expected as well as the mixed radiation spectrum.

In this context it has proven advantageous when the characteristic curves comprise at least one current-voltage curve from which the operating current Ii for each infrared emitter is determined, so that for a specified operating voltage Uᵢ and operation of a number of infrared emitters n, the total irradiation output power is reached.

The total irradiation output power Pₜₒₜₐₗ is given from the total of the operating output power Pᵢ of each infrared emitter. The following applies:

$${{{P}_{total}}_{i = 1}}^{n} = \sum {P}_{i} .$$

The corresponding operating output power is given from the operating voltage Uᵢ and the operating current Iᵢ:

Pᵢ=Uᵢ*Iᵢ.

If the operating voltage Uᵢ is specified, for each infrared emitter both the operating voltage current Iᵢ and also the operating output power Pᵢ can be determined from a current-voltage curve. It is also possible to determine the number of infrared emitters n that are needed to produce a specified total irradiation output power. Here, the infrared emitters can be operated with the same operating output power or with different operating output powers.

In an advantageous embodiment of the operating method according to the invention, the average output power density on an emitter plane is in the range from 20 kW/m² to 250 kW/m².

The output power density on the emitter plane influences the irradiation density on the substrate. On one hand, to enable the highest possible processing speed for the irradiation process and on the other hand to prevent damage to the substrate due to a too high irradiation density, for most substrates an output power density on the emitter plane in the range specified above has proven to be favorable.

In another, similarly preferred embodiment of the operating method according to the invention, the irradiation field is irradiated with an average irradiation density in the range of 10 kW/m² to 200 kW/m².

The average irradiation density with respect to the irradiation field affects the energy efficiency of the unit and the speed of the irradiation process; it should be as uniform as possible with respect to the entire irradiation field. To guarantee a high processing speed, in principle, the highest possible irradiation density is desirable. However, an average irradiation density of greater than 200 kW/m² can be associated with a strong heating and damage to the substrate. An irradiation density of less than 10 kW/m² negatively affects the processing speed; it is associated with low efficiency of the process. In addition, with an irradiation density in the range specified above, good results are achieved in drying, hardening, and sintering the coatings, adhesives, or paints, especially in the drying and sintering of metal-containing inks.

In one preferred embodiment of the operating method, it is provided that the substrate is provided with metal-containing inks and is irradiated for drying and sintering the inks.

It is a common opinion that good processing results are achieved in the drying and sintering of metal-containing inks when optical emitters are used for these processes that generate a narrow-band or discrete emission spectrum in the visible or IR-A range (see here: Z. Radivojevic et al.: Optimised curing of silver ink jet based printed traces, Proceedings of 12^{th} International Workshop on Thermal Investigations of ICs—Therminic 2006, Nice: France (2006); R. Cauchois et al.: Impact of variable frequency microwave and rapid thermal sintering on microstructure of inkjet-printed silver nanoparticles, J. Mat. Sci 47, (2012), p. 20; J. West et al.: Photonic Sintering of Silver Nano-particles: Comparison of Experiment and Theory, in Volodymyr Shatokha [Ed.]: Sintering-Methods and Products. InTech: 2012; A. Khan et al.: Laser sintering of direct write silver nano-ink conductors for microelectronic applications. Proc. SPIE 6879 (2008)).

In contrast, the irradiating device has multiple infrared emitters having a broad band emission spectrum. Preferably, the emission spectrum comprises significant radiation percentages in the IR-B and IR-C ranges. Good results are achieved if each infrared emitter emits radiation having a percentage of IR-B radiation of at least 25% and IR-C radiation of at most 13% with respect to the total radiation output power of each infrared emitter.

Metal-containing inks are a dispersion of fixed metal particles in a dispersant. The metal particles themselves have a high reflectivity for incident IR-B and IR-C radiation. The IR-B and IR-C radiation emitted by the infrared emitters and the radiation diffusely reflected by the metal particles is distributed within the layer to be dried and therefore is available mainly for irradiating the other components of the metal-containing ink. These components often comprise organic compounds that have good absorption properties for radiation having wavelengths in this range. The IR-B and IR-C radiation is normally absorbed by the dispersant and volatile substances, so that these components can evaporate. Therefore, it contributes to good drying of the ink before the metal particles are interlinked with each other in a sintering process.

In this context it has proven effective if the infrared emitters also emit radiation portions in the visible and IR-A ranges. Radiation having wavelengths in this range has higher radiation energy compared to IR-B and IR-C radiation and is suitable, in particular, for sintering the metal particles.

With respect to the device, the object mentioned above is achieved starting with a unit for irradiating a substrate of the class mentioned above such that, for the individual adjustment of a desired operating output power for each infrared emitter, a control unit is provided that individually determines, from a specified desired radiation spectrum and a specified total irradiation output power, the desired operating output power of each infrared emitter, so that when these output powers are added, the desired radiation spectrum and the total operating output power are produced, with the proviso that the infrared emitters are of an identical construction and the total irradiation output power deviates from a specified desired value by a maximum of 15%.

The irradiating device has multiple infrared emitters comprising a cylindrical emitter tube and an emitter tube longitudinal axis, wherein these emitters are arranged such that the emitter tube longitudinal axes are parallel to one another. In such a device, to be able to adjust both the total irradiation output power and also the radiation spectrum emitted by the infrared emitters, according to the invention multiple infrared emitters and a control unit are provided that determines the desired operating output power of each infrared emitter.

The position of the main emission line and thus the emission spectrum of infrared emitters are defined by their temperature. Changing the temperature of the infrared emitters also causes the wavelength distribution to change. Because the temperature of the infrared emitters depends on its operating output power, a specified radiation spectrum can be set by a suitable selection of the operating output power.

Because the device according to the invention comprises multiple infrared lamps, it is provided according to the invention that individual infrared emitters are operated with an individual desired operation output power, in order to maintain the desired spectrum. In particular, the infrared emitters can be operated with a lower operating output power (dimmed operation). The infrared emitters can be controlled individually. Because the total irradiation output power is produced from the sum of the individual operating output powers of the infrared emitters, it is also provided that individual infrared emitters can be switched off or on by the control unit in order to adjust the total irradiation output power. The suitable selection of the individual operating output powers makes it possible to adjust the emission spectrum and the total irradiation output power.

The infrared emitters are arranged in a common irradiating unit. In contrast to multiple separate emitters, such an irradiating unit requires only one common housing for the infrared emitters and thus contributes to a compact construction of the unit. The infrared emitters are arranged within the irradiating unit having their emitter tube longitudinal axes parallel to one another. By the parallel arrangement of the emitter tubes, a surface area emitter is produced that is suitable for a surface-area irradiation of the substrate with high irradiation densities.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown. In the drawings:

FIG. 1 is schematic, longitudinal sectional view of a device that can be operated according to an embodiment of the operating method according to the invention for irradiating a substrate, which here comprises four twin-tube infrared emitters;

FIG. 2 is a circuit arrangement for the heating filaments of the twin-tube infrared emitters according to FIG. 1; and

FIG. 3 is a flow chart of one embodiment of the operating method according to the invention.

### DETAILED DESCRIPTION OF THE INVENTION

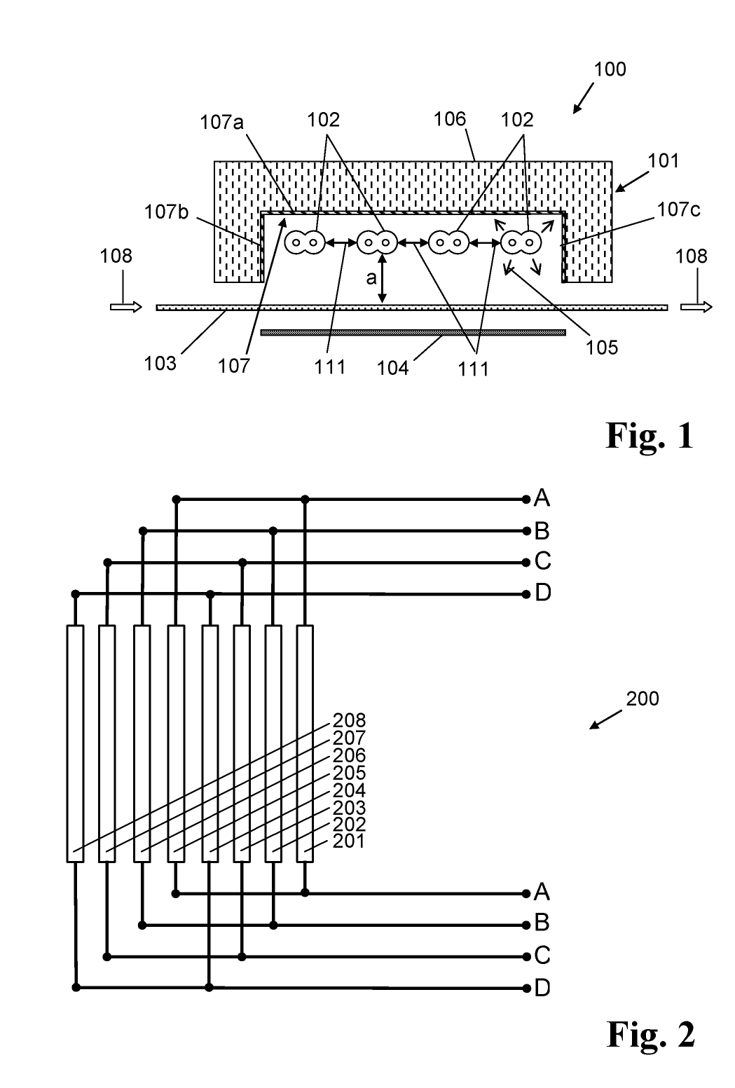

FIG. 1 shows schematically an embodiment of a device 100 for drying and sintering metal-containing ink on a substrate 103, wherein this device is operated according to an embodiment of the method according to the invention. The device 100 is used, in particular, for drying and sintering inks on printed electronic components that are produced in roll-to-roll methods.

The device 100 comprises an emitter module 101 having four infrared emitters 102 arranged in this module for emitting optical radiation 105, a reflector 107, as well as a mirror 104 for reflecting a part of the radiation 105 emitted by the emitter module 101 onto the substrate 103.

The infrared emitters 102 are structurally identical twin tube emitters having a cylindrical emitter tube longitudinal axis; they are arranged in the emitter module 101 such that their emitter tube longitudinal axes run parallel to one another and perpendicular to the direction of transport 108. As short-wave infrared emitters, the infrared emitters have a nominal color temperature of approximately 2200° C. The emission maximum of these emitters 102 is at a wavelength of approximately 1.2 μm.

The infrared emitters 102 emit radiation having a radiation percentage of IR-B radiation of greater than 25% and in the IR-C range of at most 13% of the individual total emitter output power. In the IR-A range, the infrared emitters each emit greater than 25% of the total emitter output power.

Adjacent infrared emitters 102 have a spacing 111 from each other of 55 mm. The spacing a between the emitter bottom side of the infrared emitter 102 and the substrate is 60 mm. An adjustment unit (not shown) allows a simple setting of the spacing a in a range of 35 mm to 185 mm.

The emitter module 101 has a housing 106 that is angled on two sides with one side facing the infrared emitters 102. The reflector 107 is mounted on this side. Because the reflector 107 comprises a base reflector 107a and two side reflectors 107b, 107c, a large percentage of the infrared radiation emitted by the infrared emitters 102 is coupled into the substrate 103. The reflector 107 is made of aluminum and suitable for reflecting infrared radiation having a wavelength in the range of 800 nm to 5000 nm. In one alternative embodiment (not shown), a highly reflective coating made of aluminum, silver, gold, copper, nickel, or chromium is deposited on the housing.

The emitter module 101 irradiates an irradiation field on the surface of the substrate 103. The emitter module 101 is designed for irradiating the irradiation field with an average irradiation density of approximately 150 kW/m². The irradiation field has a total surface area of 1800 cm².

The substrate 103 is a plastic film made of PET having a film thickness of 0.1 mm, which is moved by a transport device (not shown) in the transport direction 108 relative to the emitter module 101. The movement of the substrate 103 takes place at a constant forward speed.

Within the housing 106 there is a cooling element (not shown) for cooling the reflector 107 and the infrared emitters 102. The cooling element is a water cooler. This contributes to a long service life for the device, especially the emitters and the reflector layer. In one alternative embodiment, the cooling element is an air cooler. Here, the cooling element is designed so that an air flow emerging from the emitter module 101 does not cool down the substrate 103 due to its low thermal mass. This is achieved, for example, by air back-cooling of the reflector 107 or air cooling of the infrared emitter 102 and the reflector 107 with special air guidance and side air outlet.

FIG. 2 shows a circuit arrangement 200 for the heating filaments 201-208 of the twin tube infrared emitters 102 from FIG. 1. The heating filaments 201-208 are divided into a first group having four heating filaments 205-208 and a second group having four heating filaments 201-204 arranged after the first group.

The heating filaments 201 and 205, 202 and 206, 203 and 207, and 204 and 208 are connected in parallel. Heating filaments connected in parallel are operated with the same values for the operating parameters operating voltage, operating current, and operating output power. The heating filaments thus irradiate an irradiation field (not shown) composed of two identical sub-fields.

### EXAMPLE 1

The irradiating device comprises four infrared emitters having a total of eight filaments. Each infrared emitter is designed for a nominal voltage of 230 V, a nominal output power of 2620 W at a nominal temperature of 2600° C. The heated filament length is 350 mm.

At a specified total irradiation intensity of 5850 W, varying the operating voltage Uᵢ and the number of illuminated emitters n makes it possible to change the radiation spectrum, as shown in Table 1. Here, Pᵢ is the operating output power of a filament, is Pₜₒₜₐₗ is the total irradiation output power, T is the filament temperature, λₘₐₓ is the wavelength of the main emission line, and Pᵢ/Pₙₒₘᵢₙₐₗ is the ratio in percent of the individual operating output power to the nominal output power.

TABLE 1

| | Uᵢ | Pᵢ | | Pₜₒₜₐₗ | T | λₘₐₓ | Pᵢ/Pₙₒₘᵢₙₐₗ |
|---|---|---|---|---|---|---|---|
| Variant | [V] | [W] | n | [W] | [° C.] | [nm] | [%] |
| 1 | 100 | 710 | 8 | 5680 | 1830 | 1375 | 27.1 |
| 2 | 160 | 1480 | 4 | 5920 | 2250 | 1150 | 56.5 |
| 3 | 250 | 3000 | 2 | 6000 | 2700 | 1000 | 114.5 |
| 4 | 190 | 1930 | 3 | 5790 | 2415 | 1080 | 73.7 |

As Table 1 shows, a nearly constant total irradiation output power of approximately 5850 W±3% can be achieved by varying the operating voltage Uᵢ and the number n of illuminated filaments. The emission spectrum of the irradiating device therefore can be adapted at any time to a new substrate. The complicated and expensive retrofitting of emitters is eliminated.

In the following Table 2, the portion of energy in the spectral ranges VIS (380 nm-780 nm), IR-A (780 nm-1400 nm), and IR-B (1400 nm-3000 nm) is shown for different emitter temperatures.

TABLE 2

| | T | VIS | IR-A | IR-B |
|---|---|---|---|---|
| Variant | [° C.] | 380-780 nm | 780-1400 nm | 1400-3000 nm |
| 1 | 1830 | 2.2% | 22.7% | 50.5% |
| 2 | 2250 | 6.0% | 31.6% | 45.5% |
| 3 | 2700 | 8.0% | 34.3% | 43.0% |
| 4 | 2415 | 12.0% | 37.6% | 38.7% |

### EXAMPLE 2

An irradiating device for drying and sintering inks comprises an infrared emitter module having 12 twin tube infrared emitters each having 2 filaments. The total number of filaments is 24. As Table 3 below shows, by different switching of the filaments, different color temperatures can be achieved with the emitter module at an approximately constant output power density of 120 kW/m².

TABLE 3

| | | | | Output power |
|---|---|---|---|---|
| | | | | density |
| | Ui | | T | emitter field |
| Variant | [V] | n | [° C.] | [kW/m²] |
| 1 | 230 | 8 | 2600 | 124 |
| 2 | 160 | 12 | 2250 | 111 |
| 3 | 110 | 22 | 1910 | 115 |

As the substrate, both a plastic film made of polyethylene naphthalate (PEN) and also a plastic film made of polyethylene terephthalate (PET) are used, each with a film thickness of 100 μm. The plastic films were printed with an inkjet printer (Dimatix DMP283; Dropspace 25/30 μm) having silver-containing ink. As ink a dispersion of silver nanoparticles (20 weight percent) in organic solvents is used (Suntronic® Jet Silver U 5603).

The printed plastic films were then dried by the irradiating device. For this purpose, the film was moved in the transport direction at a forward speed relative to the infrared emitter module for drying and sintering the ink layer. Here, forward speeds of up to 60 m/min could be achieved.

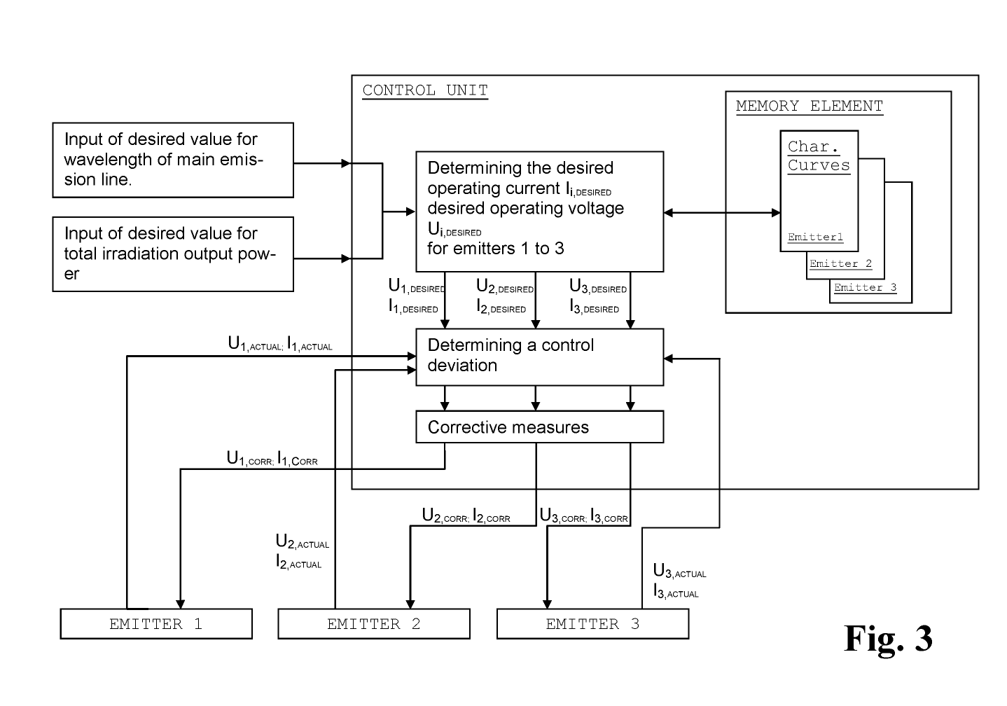

FIG. 3 shows, in a schematic diagram, a flow chart of an operating method according to the invention that forms the basis, for example, for the unit for irradiating a substrate according to FIG. 1. For simplification, FIG. 3 shows only one irradiating device having three infrared emitters that can be operated independently from each other (emitters 1-3), wherein their operating method will be explained in more detail below. Each emitter 1-3 is operated at a constant operating output power.

Initially, the irradiation process is adjusted to the substrate to be irradiated. Usually, the substrate determines the radiation spectrum to be selected and the total irradiation output power to be selected. Because the irradiation is to be performed with a specified total irradiation output power and a specified radiation spectrum, desired values are specified and are input to the control unit. The radiation spectrum is characterized essentially by the wavelength of the main emission line, so that here only the main emission line is input. In an alternative embodiment (not shown) one or more specified spectral ranges can also be considered.

Starting from these values, the control unit determines the operating output power of each infrared emitter P₁, P₂, and P₃, as well as the associated desired operating currents I_{1,DESIRED}, I_{2,DESIRED}, and I_{3,DESIRED} and desired operating voltages U_{1,DESIRED}, U_{2,DESIRED}, and U_{3,DESIRED}. The control unit has a memory element in which current-voltage characteristic curves of the emitters 1-3 are stored; it takes into account the characteristic curves when determining the desired values of the operating output power of each emitter 1-3. Determining the desired values of the individual emitter operating output powers takes place under the provision that each emitter operating output power is either 0% of the nominal output power of the infrared emitter or is in the range between 50% up to and including 100% of the nominal output power. In this way it is possible, for example, to switch off one of the emitters 1-3 while the other emitters are operated at an operating output power in the range mentioned above. In one alternative embodiment, each emitter operating output power is either 0% of the nominal output power of the infrared emitter or it is in the range from 15 up to and including 100% of the nominal output power.

The emitters 1-3 are operated by the control unit with a voltage and a current. The operating output power of the emitters 1-3 is here regulated by the control unit to the previously determined desired value, so that the emitters 1-3 irradiate an irradiation field on the surface with a total irradiation output power that deviates from a specified desired value of the total irradiation output power by a maximum of 15%.

Control deviations of the individual operating output powers of the emitters are detected by the control unit in that the operating voltages and operating currents of the emitters 1-3 are monitored continuously. Specified control deviations are corrected by the control unit such that the emitters 1-3 are operated with adjusted voltages U_{1,CORR}, U_{2,CORR}, U_{3,CORR} and adjusted currents I_{1,CORR}, I_{2,CORR}, I_{3,CORR}.

The emitters 1-3 irradiate an irradiation zone.

In one alternative embodiment of the operating method (not shown), the substrate is provided with metal-containing ink and is irradiated for drying and sintering the ink. In the irradiating unit, three additional emitters 4-6 that irradiate a second irradiation zone, as well as three additional emitters 7-9 that irradiate a third irradiation zone, are provided. The control unit controls the operating output power of each emitter 1-9 such that an irradiation field is generated with three different zones, namely the first irradiation zone, the second irradiation zone, and the third irradiation zone. The first irradiation zone is a drying zone for drying the metal-containing ink. The third irradiation zone is a sintering zone in which the metal-containing ink is sintered. The drying zone and sintering zone differ in the irradiation density. The irradiation density values of both zones are adapted to the properties of the metal-containing ink. The irradiation density of the drying zone is less than the irradiation density of the sintering zone. The second irradiation zone is a transition zone that is arranged between the drying zone and sintering zone and whose irradiation density is in the range between the irradiation density of the drying zone and the irradiation density of the sintering zone.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1.-11. (canceled)

12. A method for operating a device for modifying a substrate by irradiation with infrared radiation, the device comprising an irradiating unit in which multiple cylindrical infrared emitters having longitudinal axes arranged parallel to one another are grouped together, comprising the method steps:
(a) specifying a total radiation output power as a function of a substrate modification to be achieved;
(b) operating each infrared emitter at a desired operating output power;
(c) specifying a desired radiation spectrum as a function of the substrate modification to be achieved; and
(d) selecting the desired operating output power of each infrared emitter individually, such that, when the output powers are added together, the desired radiation spectrum and the total radiation output power are obtained;
(e) with the proviso that the infrared emitters are of an identical construction and the total radiation output power deviates by a maximum of 15% from a specified desired value.

13. The operating method according to claim 12, wherein the infrared emitters have a nominal output power and each desired operating output power is either 0% of the nominal output power or in a range from 15% to 100% of the nominal output power.

14. The operating method according to claim 12, wherein each infrared emitter emits radiation having a portion of IR-A radiation of at least 25% and a portion of IR-B radiation of at least 25%, the percentages being with respect to the total radiation power of each infrared emitter.

15. The operating method according to claim 12, wherein the desired operating output power of the infrared emitters is determined by a control unit.

16. The operating method according to claim 12, wherein the device comprises non-illuminated infrared emitters and illuminated infrared emitters, wherein adjacent illuminated infrared emitters have an illumination spacing relative to each other, wherein a variance of an average value of the illumination spacings of the device is set to a minimum.

17. The operating method according to claim 15, wherein the control unit has a memory element that stores characteristic curves of the infrared emitters and at least one of the characteristic curves is included in determining the desired operating output power of each infrared emitter.

18. The operating method according to claim 17, wherein the characteristic curves comprise at least one current-voltage characteristic curve used to determine an operating current Iᵢ for each infrared emitter, such that at a specified operating voltage Uᵢ and operation of a number of infrared emitters nᵢ the total irradiation output power is achieved.

19. The operating method according to claim 12, wherein an average output power density on an emitter plane is in a range of 20 kW/m² to 250 kW/m².

20. The operating method according to claim 12, wherein an irradiation field is irradiated with an average irradiation density in a range of 10 kW/m² to 200 kW/m².

21. The operating method according to claim 12, wherein the substrate is provided with metal-containing ink and is irradiated for drying and sintering the ink.

22. A device for modifying a substrate by irradiation, the device comprising an irradiating unit in which multiple cylindrical infrared emitters having longitudinal axes arranged parallel to one another are grouped together, a control unit for individually setting a desired operating output power for each infrared emitter, the control unit determining the desired operating output power of each infrared emitter from a specified desired radiation spectrum and a specified total irradiation output power, such that by adding together each desired operating output power, the desired radiation spectrum and the total operating output power are obtained, with the proviso that the infrared emitters are of an identical construction and the total irradiation output power deviates by a maximum of 15% from a specified desired value.
